(19) United States
(12) Patent Application Publication
(10) Pub. No.: US 2004/0154919 A1
(43) Pub. Date: Aug. 12, 2004

(54) Electric arc evaporator

(76) Inventor: Hermann Curtins, Grenchen (CH)

Correspondence Address: DENNISON, SCHULTZ, DOUGHERTY & MACDONALD, 1727 KING STREET, SUITE 105, ALEXANDRIA, VA, 22314, US

(21) Appl. No.: 10/477,746

(22) PCT Filed: Jun. 4, 2002
(86) PCT No.: PCT/EP02/06088

(30) Foreign Application Priority Data
Jun. 5, 2001 (DE) 10127013.5

(51) Int. Cl. C23C 14/34

(52) U.S. Cl. 204/298.41

(57) ABSTRACT

The invention relates to an electric arc evaporator comprising an anode, a target (14) in the form of a cathode, a voltage source which is connected to the anode and the cathode and is used to generate an electric arc spot on the target surface (16), and a magnet arrangement (66) which is situated beneath the target, comprises an inner and an outer ring coil (70, 72) and is used to produce a magnetic field influencing an electric arc movement on the target surface. The aim of the invention is to displace the electric arc on defined paths over large areas of the target surface. To this end, an element (74, 76) having high relative magnetic permeability (μᵣ>>1) and influencing the magnetic field of the ring coil in the region of the surface (16) of the target is associated to at least one of the ring coils (70, 72) of the magnet arrangement (66).

The invention relates to an arc evaporation device comprising an anode, a target acting as a cathode or connected thereto, a voltage source connected to the anode and the cathode for generating an arc or arc spot on the target or its free surface, and a magnet arrangement underneath the target and comprising an inner and an outer ring coil for generating a magnetic field influencing an arc movement on the target surface.

Arc evaporation devices are used for example for carbide coating of substrates. To do so, target material is evaporated in a vacuum chamber by an arc impacting on a target made of metal, reacts with reactive gases such as N₂, C₂H₂ introduced into the vacuum chamber and is deposited on the substrate. If the target comprises for example titanium and if nitrogen is supplied to the vacuum chamber. TiN can be deposited on the substrate to be coated. To that extent however, reference is made to adequately known technologies, similarly with regard to the voltage to be applied and the flowing current, which can be in the ranges of 10 to 50 V and more than 60 A respectively. In the vacuum chamber itself, pressure values of for example 0.0001 to 0.1 mbar (10⁻² Pa to 10 Pa) can prevail.

The current supply to the cathode can be directly thereto or via a magnetic coil, in order to move the arc spot forming on the target along a random path, for example in accordance with DE 42 43 592 A1.

EP 0 306 491 B1 describes an arc evaporation device in which a target is used to apply an alloy coating to a substrate that has at least two different metals in various active surface sections of the target.

To achieve an even erosion of the target material with large target areas too, a magnetic field with at least one closed loop is generated intermittently above the target surface in accordance with DE 35 28 677 C2.

A device of the type mentioned at the outset is shown in DE 43 29 153 A1. In this arrangement, a magnetic field is formed on the target surface by a combination of preferably two coils together with a permanent magnet (surrounded by the inner coil) in such a way that the horizontal component of the magnetic field is as constant as possible over the widest possible area of the target width. This ensures that on the one hand the arc moves in closed paths along the target and does not select in the transverse direction (parallel to the horizontal component of the magnetic field) a preferred location, and passes over everywhere with the same frequency in this transverse direction in the average time. This is referred to as “controlled arc in arc movement direction and random arc in transverse direction”. The aim is to obtain good use/erosion of the target. The drawbacks of an arrangement of this type are as follows. The strength of that proportion of the magnetic field coming from the permanent magnet changes with the erosion and can only be corrected by the coils with very great difficulty if at all. The result is non-optimum use of the target.

The voltage/current characteristic cannot be kept constant as erosion progresses, and the deposited carbide coatings suffer from changes in their properties. The possibility for variation of the magnetic field strength is limited and so certain coating properties cannot be achieved. A wide horizontal characteristic of the horizontal magnetic field component favours due to the “random arc effect” ramification of the arc with the result being stronger droplet emissions and unwelcome roughening of the coating. In addition, control of the magnetic field arrangement is relatively complex.

In all known evaporation devices, the aim is to design the magnet arrangement or magnetic device such that the following conditions are met and the following criteria are fulfilled. The magnetic field generated by the magnetic device forms with its horizontal components a closed path on the target surface. If the target surface has a rectangular geometry, the magnetic field path is always rectangular with rounded corners. Suitable field geometries can be achieved with ring coils (electromagnets), with permanent magnets or with combinations of these. It is important here that the voltage/current characteristic of the forming arc can be optimally selected and set to the target as a function of its material and coating conditions, with the current being firmly specified and the voltage depending on the existing magnetic field (parameters alterable using control system), on the bias voltages, on pressure, on the gas type etc. To do so, it is necessary that the magnetic field-strength should be variable over a wide range. Practical experience indicates here that the magnetic field strength is variable in the range from a few gauss up to around the range of 200 gauss (a few 10⁻⁴ T to about 2×10⁻² T). It is furthermore necessary that the horizontal component of the magnetic field can cover the entire target surface area in order to exploit the target material optimally. Here the movement of the magnetic field must be achieved either by controlling the coils (static MAC, MAC=Magnetic Arc Confinement) or by a mechanical movement of the MAC. Here it is understandably the static magnet arrangement that is simpler in design and hence less expensive to achieve.

Furthermore, it must be assured for the achievement of reproducible processes that the magnetic field, i.e. its horizontal component which determines the movement of the arc on the target surface, can be achieved to the required extent over the entire useful life of the target. It is of advantage here when the horizontal component of the magnetic field lines shows a steep drop, in order to suppress the splitting up of the arc into several branches, which reduces the exuding of droplets from the target with the result that the roughness of the coating being formed on a substrate is reduced.

The problem underlying the present invention is to provide the possibility of a magnetic field change in the magnet arrangement assigned to the target in such a way that the area of the target covered by the arc is increased, i.e. a widening of the erosion trench is made possible. At the same time, it should be ensured that the arc is movable on specified paths. Also, a general constancy of the voltage/current characteristic during the total life of the target should be achieved to obtain increased economic efficiency.

The problem is solved in accordance with the invention substantially in that at least one of the ring coils of the magnetic arrangement is assigned an element of high relative magnetic permeability (μr>>1) influencing the magnetic field in the area of the surface of the target and extending along the inside or outside of the ring coil extending vertically or substantially vertically to the surface of the target. In particular, it is provided that the element with high relative magnetic permeability surrounds the inner ring coil peripherally or extends all round the inside along the outer ring coil. Furthermore, the ring coils should be arranged concentrically to one another.

In order to influence the magnetic field of the inner ring coil in such a way that the maximum of the horizontal field component is shifted in the direction of the target centre, the invention provides that the inner ring coil is surrounded peripherally by the element of high relative magnetic permeability. With a pole shoe so designed and effecting a magnetic short-circuit, the field lines are accordingly prevented from shifting in the direction of the outer ring coil.

With regard to the outer ring coil, the element of high relative magnetic permeability runs between the outer coil and the inner coil, i.e. on the inside along the outer ring coil, by which the magnetic field of the outer ring coil is forced outwards. Hence magnetic field changes caused by the elements of high relative magnetic permeability, referred to as pole shoes, provide the possibility of aligning the horizontal components of the magnetic fields on the target surface in such a way that the latter can be covered by the arc spot over a greater area.

The element of high relative magnetic permeability is an element made from magnetic material such as iron, steel or iron alloys such as permalloy. The element should here have a relative magnetic permeability pr of preferably μr≧106.

With the teachings in accordance with the invention, an increase in the erosion width in a target is achievable, which in turn results in an increase in the productivity of a corresponding arc evaporation device. The technical solution is of simple design and is inexpensive. Since a stationary, i.e. mechanically non-adjustable magnet arrangement is also used, hardly any disruptions need to be feared. Permanent magnets are avoided. It is also possible to achieve magnetic field strengths in the range from 10⁻⁵ T to 10⁻² T or higher values without difficulty.

Even if the teachings in accordance with the invention are preferably achievable with a magnet arrangement having an inner and an outer ring coil, it is also possible to use a magnet arrangement with only one ring coil, which in line with the teachings in accordance with the invention are assigned an element of high relative magnetic permeability influencing the magnetic field of the ring coil in the area of the surface of the target, where the element preferably surrounds the ring coil peripherally and the magnet arrangement itself is adjustable in the x and/or y direction in a plane running parallel to the target surface. If necessary an adjustment vertical to the target surface, i.e. to the z axis, is possible.

Further details, advantages and features of the invention are shown not only in the claims and in the features they contain—singly and/or in combination—but also in the following description of preferred embodiments shown in the drawing.

In the drawing

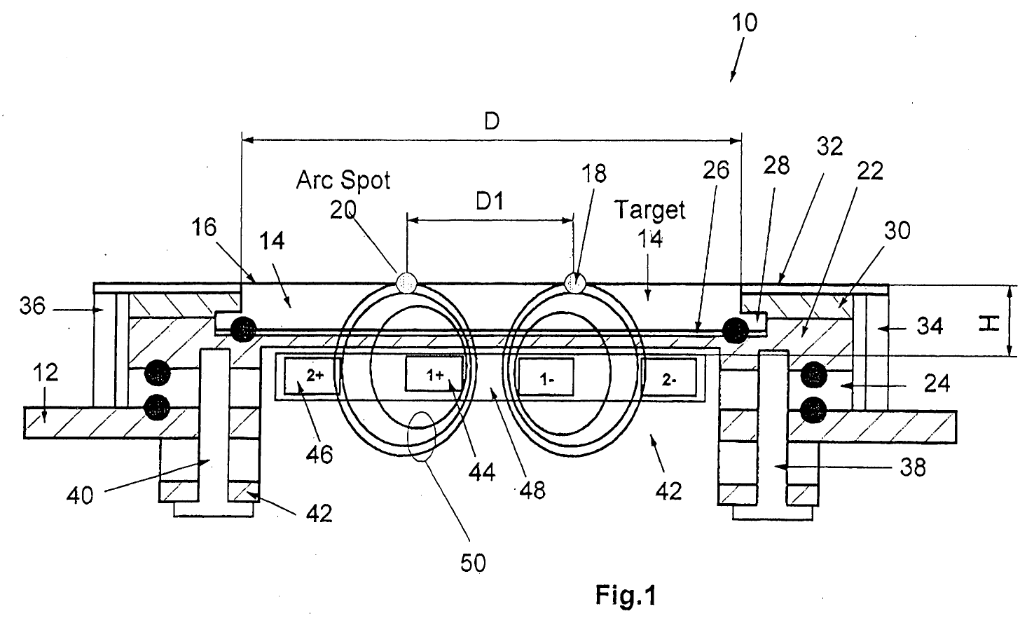

FIG. 1 shows a principle view of a magnet arrangement having two ring coils, the inner of which is subjected to current.

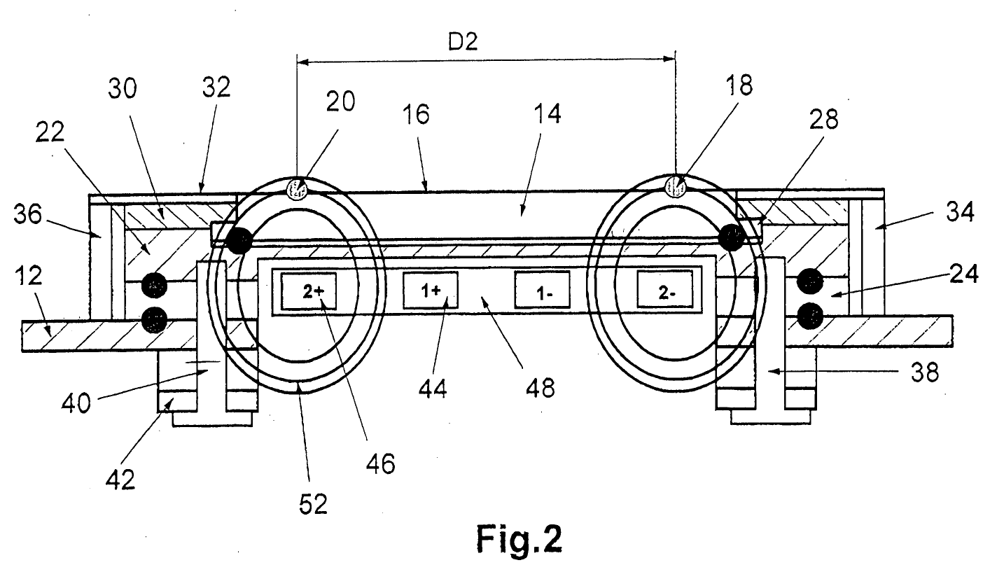

FIG. 2 shows a magnet arrangement corresponding to FIG. 1 with outer ring coil subjected to current,

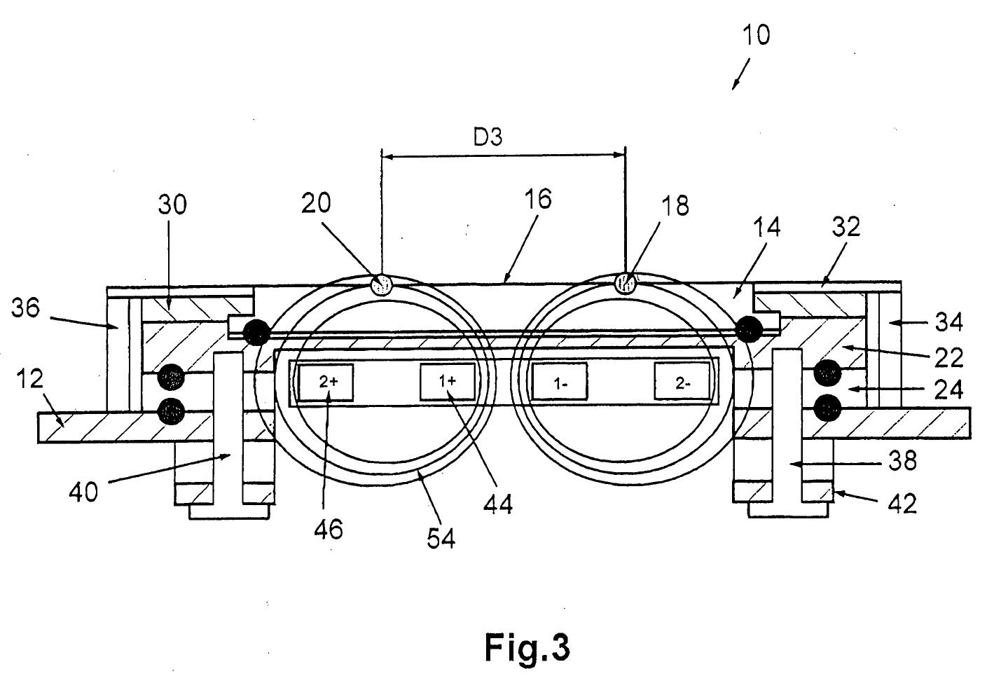

FIG. 3 shows the magnet arrangement according to FIGS. 1 and 2 with inner and outer ring coils subjected to current,

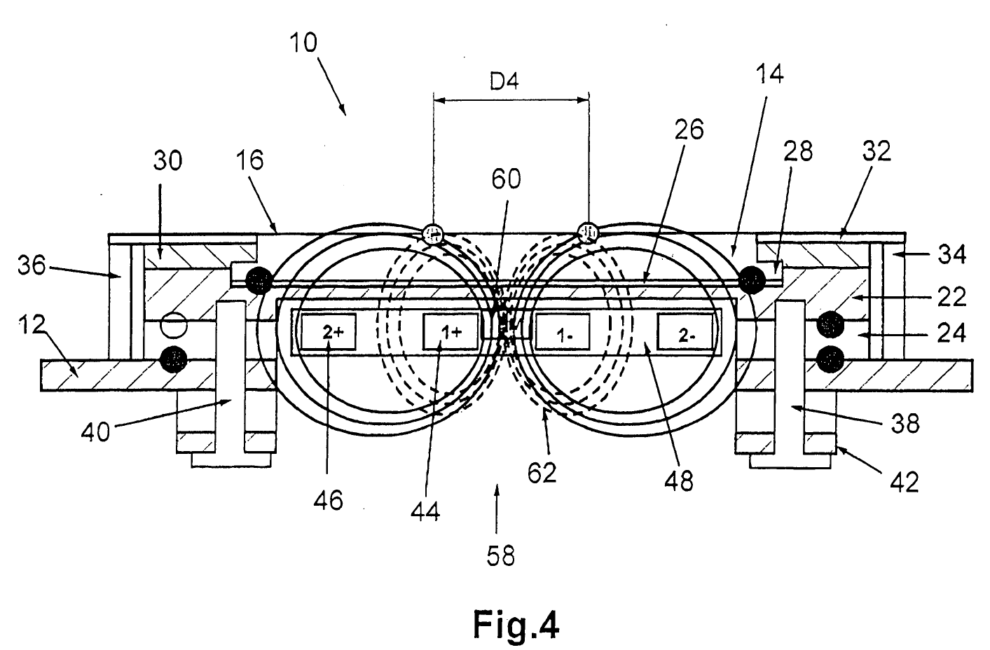

FIG. 4 shows a magnet arrangement with ring coils and permanent magnets,

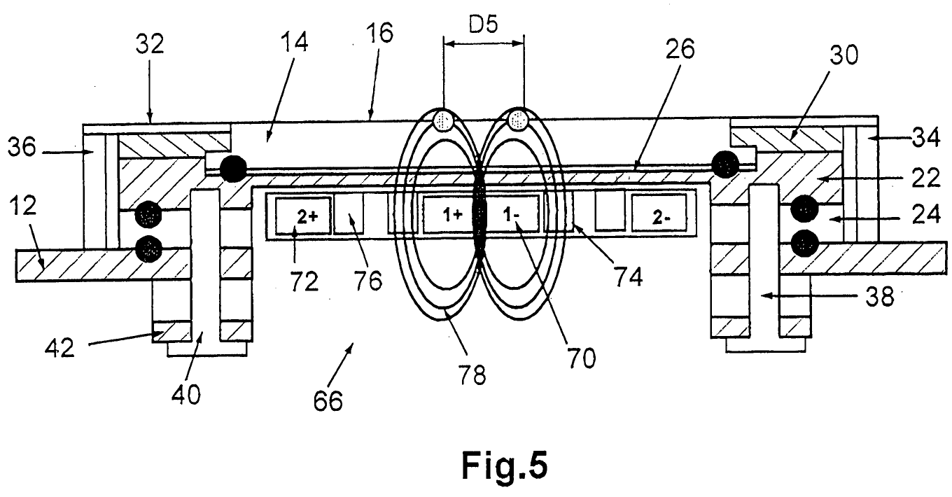

FIG. 5 shows a principle view of a magnet arrangement in accordance with the invention with inner ring coil subjected to current,

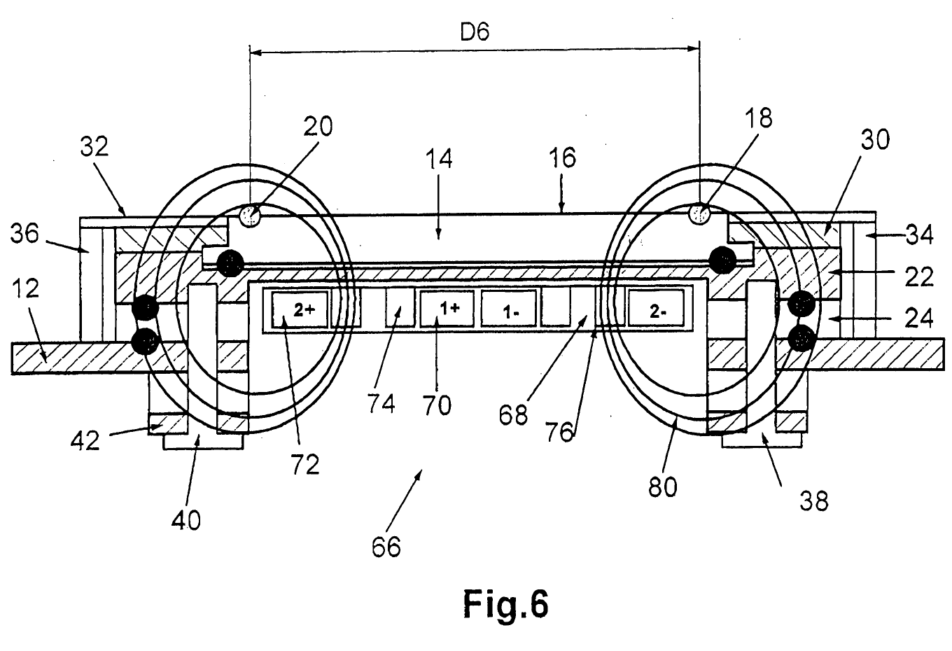

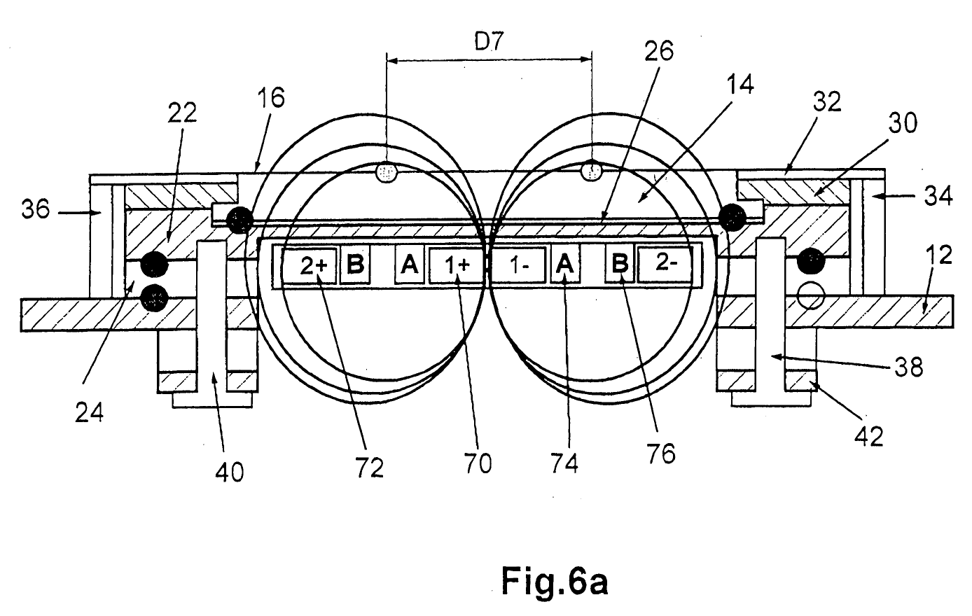

FIG. 6 shows a magnet arrangement corresponding to FIG. 5 with outer ring coil subjected to current,

FIG. 6a shows a magnet arrangement corresponding to FIG. 5 and FIG. 6 with both ring coils subjected to current,

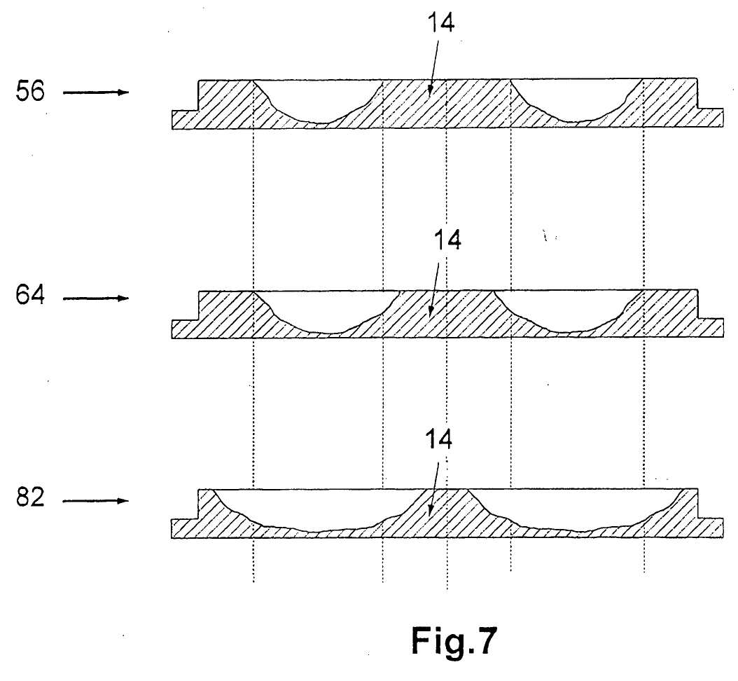

FIG. 7 shows typical erosion profiles achieved with magnet arrangements of FIGS. 1 to 6,

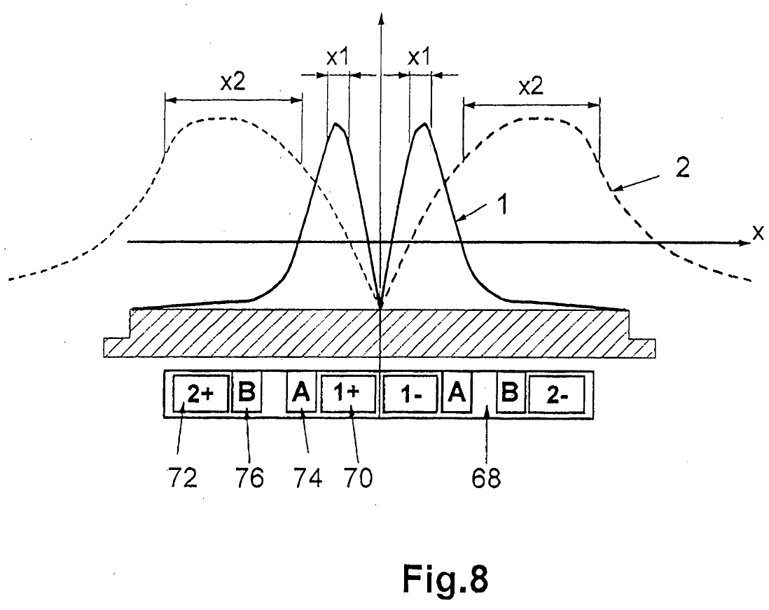

FIG. 8 shows the course of a magnetic field strength generated with an arrangement in accordance with the invention along the surface of a target,

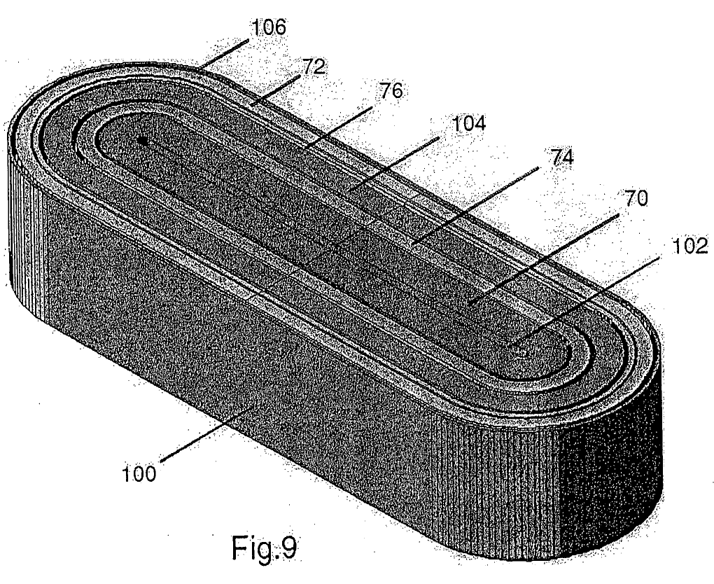

FIG. 9 shows a perspective view of a first embodiment of a magnet arrangement,

FIG. 10 shows the magnet arrangement according to FIG. 9 in plan view,

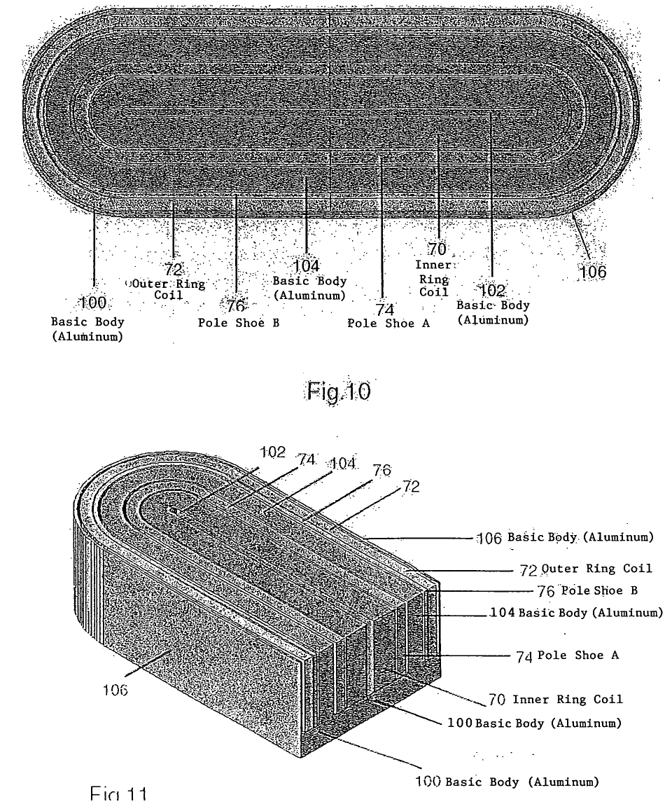

FIG. 11 shows the magnet arrangement according to FIGS. 9 and 10, however in section.

FIG. 12 shows a plan view of a further embodiment of a magnet arrangement and

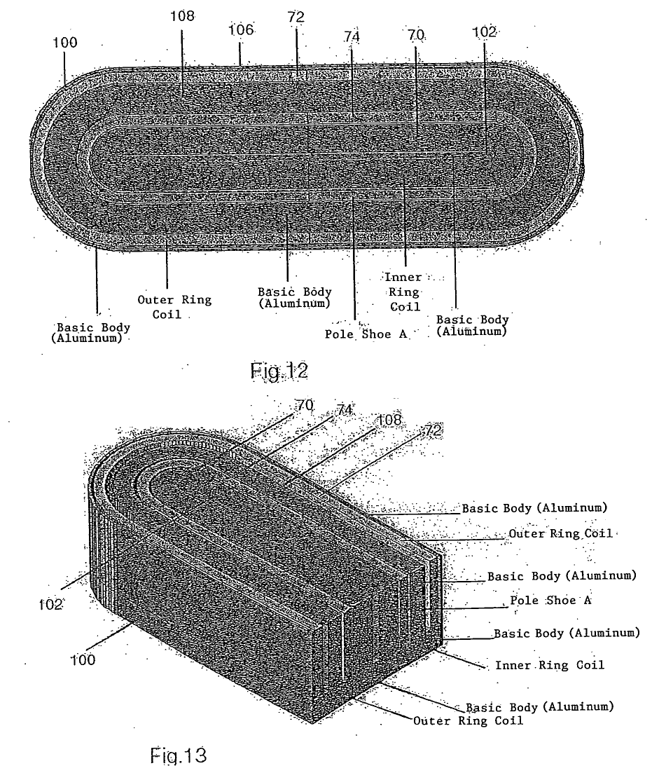

FIG. 13 shows the magnet arrangement according to FIG. 12 in a perspective view and in section.

On the basis of the figures, in which as a general principle identical elements are provided with identical reference numbers, magnet arrangements intended for arc evaporation devices are to be described that on the one hand conform to the prior art (FIGS. 1 to 5) and on the other hand follow the teachings in accordance with the invention (FIGS. 6 to 13). Regardless of this, it must be noted that the arrangements of target and current supply shown in principle in the figures have a per se inventive content, even if an explanation is provided in connection with known magnet arrangements.

FIGS. 1 to 6 show purely in principle a cathode element 10 that can be fastened using a flange plate 12 in a housing of a vacuum chamber of an arc evaporation device. Here the cathode element 10 comprises a target 14 whose free surface (target surface 16) on the vacuum chamber side is evaporated by means of an arc spot 18 or 20 to be moved on this surface. The evaporated material then reacts with reactive gas such as N₂ or C₂H₂ introduced into the vacuum chamber and is deposited on a substrate, not shown, located inside the vacuum chamber. If the target 14 is for example titanium, and if nitrogen is introduced into the vacuum chamber, titanium nitride is deposited onto the substrate.

For evaporating target material, a voltage is applied via a voltage source between the target 14 and the housing of the vacuum chamber, where the housing is the anode and the cathode element 10 and hence the target 14 are the cathode. To that extent, reference is made to adequately known technologies, similarly with regard to the voltage applied in the order of size of 10 to 50 V and with a current of preferably more than 60 A. The pressure in the vacuum chamber can for example be 0.0001 to 0.1 bar (10⁻² Pa to 10 Pa) depending on application, just to state examples for values.

In accordance with a noteworthy embodiment, the target 14 extends from a carrier 22 which in turn is electrically insulated by an insulator 24 from the flange plate 12, which for example consists of aluminium. The carrier 22 and the target 16 are at a distance from one another to provide a cavity 26 in order to fill this with a cooling medium. Furthermore, the target 14 has on the bottom side an all-round flange 28 using which the target 14 is fixed between the carrier 22 and a fastening plate 30 above the target 14. The fastening plate 30 itself is covered by an insulator 32 for example of BN and connected via insulators 34, 36 to the baseplate 12.

The target 14 or the carrier 22 is connected using bolts, screws or elements 38, 40 with the same effect to an electrical connection 42, in particular in the form of a ring conductor leading to a voltage source.

In order for the arc spot 18, 20 forming when voltage is applied between the anode and the cathode to be moved on the surface 16 of the target 14 along a specified path in order to remove material from this target, a magnet arrangement is provided underneath the target 14 and outside the vacuum chamber, with the embodiments in FIGS. 1 to 4 showing those arrangements that are known from the prior art.

For example, FIG. 1 shows a magnet arrangement 42 that comprises two ring coils 44, 46 which run substantially parallel in one plane that extends parallel to the surface 16 of the target 14. The ring coils 44, 46 are mounted in a housing 48 comprising for example plastic or aluminium. The holder 48 and hence the ring coils 44 are stationarily arranged. Furthermore, the ring coils 44, 46—as also in the teachings in accordance with the invention—are concentric to one another and symmetrical to the longitudinal axis of the target 14. To that extent however reference is made to known ring coil arrangements and alignments.

In FIG. 1, the inner ring coil 44 is subjected to current so that the maximums of the horizontal components of the magnetic field lines 50 have a distance D1. If the outer ring coil 46 in the arrangement shown in FIG. 1 is subjected to current when the inner ring coil 44 is switched off, the distance between the maximums of the horizontal components of the magnetic field lines 52 is D2. In FIG. 3, both ring coils 44, 46 are subjected to current, so that a maximum of the horizontal component of the magnetic field lines 54 is the distance D3, where it is clear that D2≧D3≧D1.

Hence a path of the arc spot 18, 20 predetermined by the horizontal course of the magnetic field lines can erode at most the area D2−D1 relative to the width D of the target 14, with the result that an erosion profile 56 in FIG. 7 is obtained in the target 14, i.e. by appropriate control of the coils 44, 46. The difference of D2−D1 is small in comparison with the width D of the target 14. Typical values are D2−D1≦0.5 D. The cause of the narrow eroded area of the target is that the field lines of the inner ring coil 44 are pushed in the direction of the outer ring coil 46, since the magnetic flux between the coils 44 and 46 is large. The result of this is that the area D1 is relatively large. Although the attempt could be made to reduce the distance D1 by generating high field strengths with the inner ring coil 44, high field strengths mean that the geometric extent of the ring coil is increased, as a result of which D1 would again have to be increased.

In other words, the result with the stationary magnet arrangement 42 according to FIGS. 1-3 is a relatively small area of target erosion, so that with expensive target materials high production costs are entailed for the formation of coatings.

FIG. 4 shows an embodiment of a magnet arrangement 58 with the cathode element 10 corresponding to FIGS. 1 to 3, which has in addition to two ring coils 44, 46 running coaxially to one another a permanent magnet 60 which is surrounded by the inner ring coil 44 and is arranged in the centre of the target 14, as proposed by DE 43 29 155 A1. The embodiment shows the magnetic field lines 60 when the inner coil 44 is subjected to current which result from superimposition of the magnetic field of the inner coil 44 and of the magnetic field of the permanent magnet 60. The maximums of the horizontal components of the magnetic field lines 62 are at a distance D4. Although there is an improvement in the difference D2−D4 when the inner coil 44 is not subjected to current and when the outer coil 46 is actuated, there is the drawback that the magnetic field strength of the permanent magnet 60 is generally always present and can only be compensated with considerable effort by the coils 44, 46. As a result, the magnetic field strength to be set is restricted. In practice, it has been shown that when erosion is advanced, process control by the coils 44, 46 is no longer possible to the required extent for obtaining reproducible results, with the result that the targets have to be replaced quite early on. An erosion profile corresponding to the arrangement in FIG. 4 is identified in FIG. 7 with the reference number 64. A comparison with the erosion profile 56 shows a greater width for the erosion trench.

Alternatively, a target could be assigned exclusively a magnet arrangement having a permanent magnet. In this case, it would be necessary to move the permanent magnet at least in x and y in a plane parallel to the surface of the target. An additional movement vertical to the target surface 16, i.e. in the z direction, leads to a change in the magnetic field strength itself and in particular to its course.

FIGS. 5 and 6 show the principles of magnet arrangements 66 following the teachings in accordance with the invention.

The magnet arrangement 66 comprises a holder 68 made for example from plastic or aluminium and containing an inner ring coil 70 and an outer ring coil 72 concentric to the inner one. The ring coils 70, 72 follow approximately the geometry of the target 14 itself and have in the plan view a rectangular form with rounded corners. Also, the ring coils 70, 72 run in a plane that extends parallel to the surface 16 of the target 14. Furthermore, there is a symmetry to the longitudinal axis of the target 14.

In divergence from the known arrangements, the inner coil 70 is surrounded concentrically by an all-round pole shoe 74 made of a ferromagnetic material such as iron or steel or an alloy such as permalloy, i.e. a material having a high relative magnetic permeability μr with μr in particular≧104, preferably ≧106.

The outer ring coil 72 is also limited on the inside by a pole shoe 76 of suitable material and coaxial to the pole shoe 74. FIGS. 5 and 6 furthermore show the magnetic field lines when the inner ring coil 70 alone is switched on or when the outer ring coil 72 (FIG. 6) alone is switched on.

In accordance with the view in FIG. 5, it can be seen that the distance of the maximums of the horizontal components of the field lines 78 generated by the inner ring coil 70 is D5, whereas the distance of the maximums of the horizontal components of the magnetic field lines 80 has the value D6 when current is flowing through the outer ring coil 72 and the inner ring coil 70 is switched off. It is clear that the difference D6−D5 is considerably greater than the differences D2−D1 in accordance with the embodiment in FIGS. 1 to 3 and also than the corresponding difference according to FIG. 4. The result is a wider erosion—profile 82 in accordance with FIG. 7. This in turn means that an increase is obtained in the productivity of an arc evaporation device with a magnet arrangement 66 in comparison with what is known, simultaneously with freely selectable impedance regardless of the erosion state.

The explanation for the greater difference, i.e. the width of the erosion trench, can be stated as follows. The pole shoe 74 peripherally surrounding the inner ring coil 70 and made from a material of high relative magnetic permeability has the effect that a large proportion of the magnetic field lines flows through the pole shoe 74 when the coil 70 is subjected to current, since the pole shoe's magnetic resistance is low. Regardless of this, the field lines 78 must flow in the central area of the ring coil 70 (along the central axis of the target 14).

The magnetic short-circuit of the pole shoe 74 prevents the field lines being forced in the direction of the outer ring coil 72, so that the maximum of the horizontal component of the field 78 is forced to the target centre, i.e. the distance D5 becomes smaller than that in the embodiment of FIGS. 1 to 4. If the outer ring coil 72 is subjected to current, the opposite effect occurs. The magnetic short-circuit of the pole shoe 76 running along the inside of the outer ring coil and concentrically to it, effects a change in the magnetic flux with the result that the magnetic field lines 80 are forced outwards, so that an increase in the distance of the maximums of the horizontal components of the field is achieved. This distance is identified with D6 in FIG. 6. The result is a greater difference of D6 and D5, and hence improvement in the use of the target and simultaneous increase in the dynamics. The shift in the maximums of the magnetic field line is—as in the prior art—achieved by corresponding variation of the currents applied to the ring coils 70, 72 or by switching the current on and off.

FIG. 6a shows a magnet arrangement corresponding to FIGS. 5 and 6 in which both the inner ring coil 70 and the outer ring coil 72 are subjected to current. The maximum horizontal component of the magnetic field thus generated moves inwards or outwards depending on the current supply to coils 70, 72. In the embodiment, the maximum component of the effective magnetic field is indicated with a distance D7.

FIG. 8 shows purely in principle the horizontal component of the magnetic field strength H opposite the target 14, starting from the centre point of the latter, to which the ring coils 70, 72 and the pole shoes 74, 76 run symmetrically. The magnetic field strength, i.e. the horizontal component of the inner coil 70, is narrow and falls steeply (continuous line), whereas the magnetic field strength effected by the outer ring coil 72 is wide and gently falling. As a result of this, there is only a narrow path for the arc spot 18, 20 moving on the target surface 16, the consequence of which is that there is no ramification of the movement and hence a reduction in droplets is achievable.

As a general point, it may be noted for FIG. 8 that it shows the change of the horizontal component of the magnetic field in principle as the latter is perceived by the arc on the target surface. Due to the favourable ionisation effect of the magnetic field (horizontal component), the arc prefers to move along paths where higher fields prevail. If the horizontal component of a magnetic field follows the course of a curve 1 in accordance with FIG. 8, i.e. a steeply falling curve, the arc will dwell/move above all inside the area of width x1. If the horizontal component of the magnetic field however has the course 2 in FIG. 8, the arc will stay in the area x2, where x2>>x1. In the case of the magnetic field course of curve 1, therefore, the arc is significantly more localised and controlled.

This also shows clearly that with the inner and outer ring coils 70, 72 switched on, the pole shoes 74, 76 are no longer of so crucial importance, and instead have the effect of increasing the erosion width.

Comparative tests between magnet arrangements to the prior art in accordance with FIGS. 1 and 4 and as per the teachings in accordance with the invention have led to the following. In all tests, the targets 14 have a width D of 140 mm. The length was 750 mm. The distance between target surface 16 and the surface of the respective holder 48, 68, indicated with H in FIG. 1, was 25 mm. The inner and outer ring coils 44, 46 and 70, 72 used each had the same dimensions, where the inner ring coil 44, 70 was characterised by 3200 Ampere windings with a width (parallel to the target surface 16) of 22 mm and a height (vertical to the target surface) of 55 mm. The outer ring coil 46, 72 had 2500 A windings with a width of 18 mm and a height of 55 mm. In the arrangement according to FIGS. 1 to 3, i.e. with only two ring coils concentric to one another, the horizontal magnetic field strength was set to 0 to 40 gauss in the area between the maximums of the horizontal components. The result was a value of 80 mm for the distance D1 and a value of 115 mm for the distance D2, so that a difference of 35 mm resulted. In the magnet arrangement 58 with permanent magnets 60 in the centre point of the target 14 or along its central axis, the result was a horizontal magnetic field strength of 20 to 50 gauss between the maximums of the horizontal components of the magnetic field lines, where D4 was 55 mm and D2 was 120 mm, such that the resultant difference was 65 mm.

The previously reproduced results were as a general principle achieved with current strengths passing through the coils of typically 8 A to 10 A with 250 to 350 windings.

In the magnet arrangement 66 following the teachings in accordance with the invention, the horizontal magnetic field strength could be varied in the range between the maximums of the horizontal components between 0 and 80 gauss, with the values D5=30 mm and D6=120 mm, i.e. a difference D6−D5 of around 90 mm, resulting between the maximums.

Tests have shown that in comparison to known arrangements, improved erosion profiles can be achieved even when only the inner ring coil 70 has been assigned this concentrically surrounding pole shoe 74 of a material with high relative magnetic permeability.

FIGS. 9 and 13 show the principle views of magnet arrangements following the teachings in accordance with the invention. The magnet arrangement in FIGS. 9 to 11 thus comprises a housing of aluminium—if necessary also of plastic—designated as the basic element 100 and arranged parallel to the surface 16 of the target 14. The inner ring coil 70 which is surrounded by the pole shoe 74 concentrically surrounding it is arranged inside the basic element 100. The inner ring coil 70 surrounds in the embodiment a web-like section 102 of the basic element 100 that runs along the central axis of the target 14 and vertical to its transverse axis. The inner pole shoe 74 is in turn limited by a wall 104 of the basic element 100 concentrically surrounding the inner ring coil 70 and the inner pole shoe 74, along the outside of which wall runs the second pole shoe 76 assigned to the outer ring coil 72. Finally, the outer ring coil 72 is surrounded by the outer wall 106 of the basic element 100.

It must be noted that the web 102 should be as narrow as possible—practically around 0—or if necessary replaced by “air” or a non-magnetic material such as plastic in order to further reduce the distance D5 shown in FIG. 5.

It is clear from the views in FIGS. 9, 10 and 11 that the ring coils 70, 72 and the pole shoes 74, 76 assigned to them are concentric to one another and are aligned to the longitudinal or transverse axis of the target 14.

The embodiment of FIGS. 12 and 13 differs from that in FIGS. 9 to 11 in that only the inner ring coil 70 is assigned a pole shoe 74, whereas the outer ring coil 72 is limited on the inside and outside by sections of the basic element 100, i.e. outer wall 106 and intermediate wall 108, which correspond in function to the wall 104 in accordance with FIGS. 9 to 11.

Typical dimensions for the pole shoes 74, 76 and the ring coils 70, 72 are as follows: the inner pole shoe 74 can have a width from 5 to 10 mm with a height corresponding to that of the inner ring coil 70, for example 60 mm. As regards the outer pole shoe 76, a width of 3 to 8 mm is preferable, where the height is that of the outer ring coil, i.e. 60 mm, for example. The ring coils 70, 72 themselves are subjected to currents of preferably 0 to 20 A.

1. An arc evaporation device comprising an anode, a target (14) acting as a cathode or connected thereto, a voltage source connected to the anode and the cathode for generating an arc or arc spot (18, 20) on the target or its free surface (16), and a magnet arrangement (66) underneath the target and comprising an inner and an outer ring coil (70, 72) for generating a magnetic field influencing an arc movement on the target surface,
wherein
at least one of the ring coils (70, 72) of the magnetic arrangement (66) is assigned an element (74, 76) of high relative magnetic permeability (μr>>1) influencing the magnetic field of the ring coil in the area of the surface (16) of the target, where the element assigned to the inner ring coil (70) peripherally surrounds the inner ring coil and the element assigned to the outer ring coil (72) extends along that surface of the outer ring coil facing the inner ring coil.

2. Arc evaporation device according to claim 1,
wherein
the element (74, 76) runs all round or substantially all round concentrically to the inner ring coil (70) or the outer ring coil (72).

3. Arc evaporation device according to claim 1 or claim 2,
wherein
the element (74, 76) has a relative magnetic permeability μr with μr≧104, in particularμr≧106.

4. Arc evaporation device according to at least one of the previous claims,
wherein
the element (74, 76) comprises a ferromagnetic material.

5. Arc evaporation device according to at least one of the previous claims,
wherein
the element (74, 76) comprises iron, steel or an alloy such as permalloy.

6. Arc evaporation device according to at least one of the previous claims,
wherein
the arc is movable on account of the magnetic field generated by the magnetic arrangement (66) substantially along specified paths on the target surface (16), avoiding splitting into main and secondary branches.

7. Arc evaporation device according to at least one of the previous claims,
wherein
at least the inner ring coil (70) is surroundd by the element of high relative magnetic permeability (μr>>1).

8. Arc evaporation device according to at least one of the previous claims,
wherein
the magnetic fields generated by the ring coils (70, 72) and acting in the area of the target surface (16) on the arc spot (18, 20) can be influenced by the elements (74, 76) of high relative magnetic permeability assigned to the outer and inner ring coils (70, 72) such that the magnetic field generated by the inner ring coil can be moved towards the target centre and the magnetic field generated by the outer ring coil can be moved towards the target edge.

9. Arc evaporation device according to at least one of the previous claims
wherein
the longitudinal axis of the target (14) and the longitudinal axes of the ring coils (70. 72) run in a common plane extending vertically to the target surface (16).

10. An arc evaporation device comprising an anode, a target (14) acting as a cathode or connected thereto, a voltage source connected to the anode and the cathode for generating an arc or arc spot (18, 20) on the target or its free surface (16) and a magnet arrangement (66) underneath the target and comprising at least one ring coil (70, 72) for generating a magnetic field influencing an arc movement on the target surface,
wherein
the at least one ring coil (70, 72) of the magnetic arrangement (66) is peripherally surrounded by an element (74, 76) of high relative magnetic permeability (μr>>1) influencing the magnetic field of the ring coil in the area of the surface (16) of the target and wherein the magnetic arrangement is adjustable at least in an x and/or y direction running parallel to the target surface.

11. Arc evaporation device according to claim 10,
wherein
the magnetic arrangement (66) is adjustable vertical to the target surface (16) in the z direction.
